(19) United States
(12) Patent Application Publication
(10) Pub. No.: US 2014/0215120 A1
(43) Pub. Date: Jul. 31, 2014

(54) SYSTEM, METHOD AND COMPUTER PROGRAM PRODUCT FOR GENERATING CHRONOLOGICALLY ORDERED GLOBALLY UNIQUE IDENTIFIERS

(71) Applicant: Inmar, Inc., Winston-Salem, NC (US)

(72) Inventors: David Lee SAYLOR, Johnson City, TN (US); Shawn Page Fitzgerald, Winston Salem, NC (US)

(21) Appl. No.: 13/754,115

(22) Filed: Jan. 30, 2013

(51) Int. Cl. G06F 12/02; G06F 12/00; G11C 7/10

(52) U.S. Cl. CPC G06F 12/0238; G11C 7/1072; G06F 12/00
USPC 711/102; 711/104; 711/156

(57) ABSTRACT

A computer-based system, method and computer program product for generating chronologically based globally unique identifiers.

### FIELD OF THE INVENTION

The present invention generally relates to a computer implemented system and method of generating chronologically ordered universally unique identifiers (“UUIDs”).

### BACKGROUND OF THE INVENTION

Computer data systems use data keys (primary keys and foreign keys) to identify data records. These keys are used to relate data records, for example, by associating order detail records to the corresponding order records. The key value assigned to a data record should be unique in the context in which the data record resides (e.g., a data table).

It is known to use universally unique identifiers (“UUIDs”), which may also be referred to as globally unique identifiers (“GUIDs”), in a manner that theoretically allows key values to be assigned anywhere and used everywhere. Using UUIDs is helpful when data is created in various locations and aggregated centrally for processing. For example, using UUIDs breaks the real-time dependence on the central data store for managing key value assignments.

As an example, UUIDs may be useful in implementing a system for generating and processing electronic promotional offers. Electronic promotional offers, similar to paper coupons, encourage consumers to visit a retailer's virtual or physical store, while giving the consumer a discount for the consumer's purchase of an item at that retailer. While paper coupons remain popular with consumers, retailers and manufacturers, the number of electronic promotional offers distributed to, acquired and redeemed by consumers is increasing. Electronic promotional offers may be distributed through a variety of networked computer devices such as personal computers, mobile phones, smart phones, or other portable electronic devices. Retailers and/or manufacturers may work with one or more digital coupon publishers to distribute electronic coupons to consumers. The consumer may present and redeem the coupons at a particular retailer if that particular promotion is associated with that particular retailer's point-of-sale (“POS”) system. Retailers may use POS integration providers (“PIP's”) to associate electronic promotions with their own point-of-sale systems. In systems for producing and processing electronic promotional offers, it may be desirable for each instance (e.g., for each “coupon”) to be associated with a unique identifier, such as a UUID.

Several versions of prior UUIDs are known. For example, FIG. 1 shows a bitmap of a prior art UUID 10, which is sometimes referred to as UUID Version 1. UUID 10 includes 128 bits from 0-127 and seven fields 12, 14, 16, 18, 20, 22, 24 having 48 bits, 16 bits, 4 bits, 4 bits, 8 bits, 16 bits and 32 bits, respectively. As schematically shown in FIG. 1, the bits are numbered from right to left, starting at 0 and ending with 127.

As shown in FIG. 1, field 12 stores a node identification number or random number. The node identification number of field 12 is the Media Access Control (“MAC”) address of the system (e.g., computer) that generated the UUID 10. Field 14 may store a portion of a clock sequence multiplexed with a variant. Field 16 stores a first portion of a high field of a timestamp. Field 18 stores the version of the format of the UUID. Field 20 stores a second portion of a high field of the timestamp. Field 22 stores a medium field of the timestamp. Field 24 stores a lower field of the timestamp. Problems related to, for example, security and privacy have been encountered with the UUID 10, since it may include both the MAC address and the timestamp of the system that created it. The UUID may also be larger than required for some applications.

Another prior art UUID, which is known as UUID Version 4, also has 128 bits, but rather than having the above-discussed fields, a pseudo random number occupies all of the bits, except for those reserved to identify the UUID as Version 4. That is, the size of UUID Version 4 has remained constant at 128 bits. While size may be becoming less of an issue as computer resources such as RAM have become more plentiful, size does still have performance implications. Another problem that has been encountered with UUID Version 4 is that completely random ordering makes optimal record creation and insertion inefficient because indexes on primary and foreign keys must be constantly rebuilt to reorder the index as each new record is inserted.

As another example, sequential UUIDs are known that avoid the random ordering problem mentioned above. When a databases utilizes sequential UUIDs, the database initializes a GUID value when the system starts, then each time it creates a new sequential GUID value, it increments the current value. Therefore, each value generated is larger than previously generated values. But this known solution requires all values to be assigned by the target database, which is constraining. Furthermore, values created after a system restart are not guaranteed to be greater than values created before the system restart because the sequential GUID generator may re-initialize with a randomly selected value.

In view of the above-discussed problems, using UUIDs as data keys has, in some instances, been limited to the most performance tolerant applications. Whereas UUIDs other than those discussed above have been developed, there is still a need for UUIDs that provide a new balance of properties.

### BRIEF DESCRIPTION OF THE DRAWINGS

FIG. 1 is a bitmap of a prior art UUID.

FIG. 2 is a bitmap of an exemplary UUID, in accordance with an aspect of this disclosure.

FIG. 3 is a bitmap of an exemplary, relatively large UUID, in accordance with one aspect of this disclosure.

FIG. 4 is a bitmap of an exemplary, relatively medium-sized UUID, in accordance with another aspect of this disclosure.

FIG. 5 is a bitmap of an exemplary, relatively small UUID, in accordance with another aspect of this disclosure.

FIG. 6 is a process flow diagram illustrating an exemplary process for generating universally unique identifiers, in accordance with an aspect of this disclosure.

FIG. 7 is a process flow diagram illustrating an exemplary process for providing current time values, as part of generating universally unique identifiers, in accordance with an aspect of this disclosure.

FIG. 8 is a diagram illustrating exemplary computer hardware and software for implementing an embodiment of the invention.

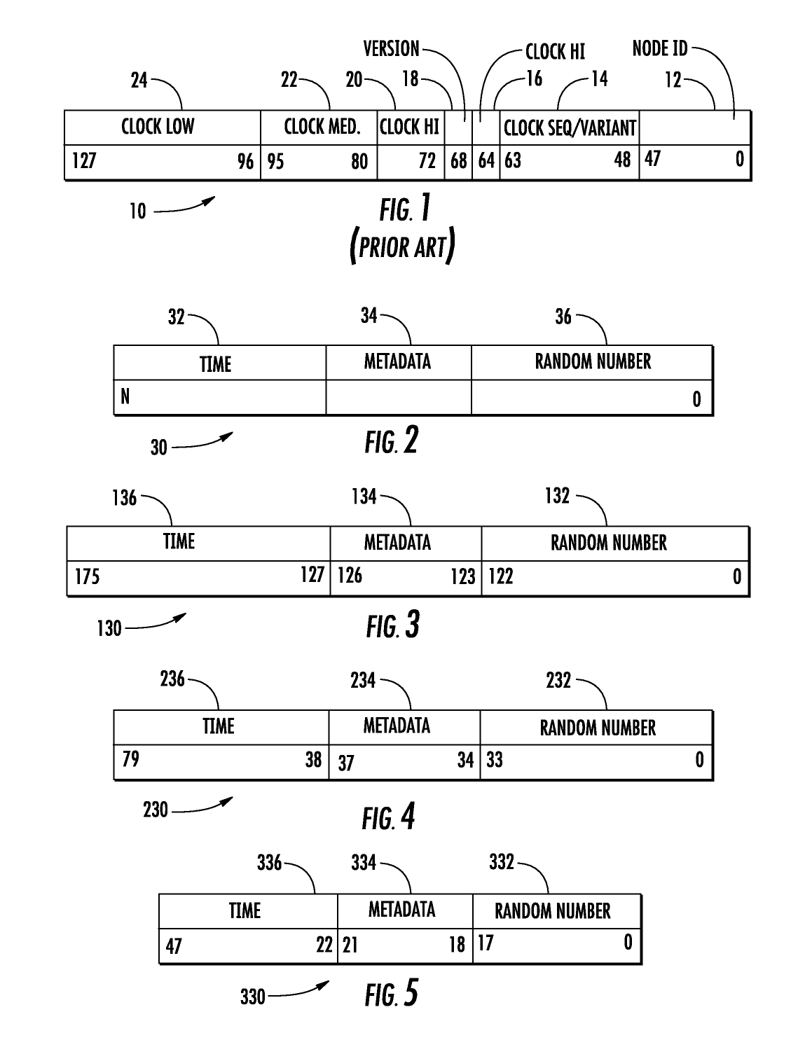

### DETAILED DESCRIPTION OF PREFERRED EMBODIMENTS

Reference will now be made in detail to the presently preferred embodiments of the invention, one or more examples of which are illustrated in the accompanying drawings. Each example is provided by way of explanation of the invention, not limitation of the invention. In fact, it will be apparent to those skilled in the art that modifications and variations can be made in the present invention without departing from the scope or spirit thereof. For instance, features illustrated or described as part of one embodiment may be used on another embodiment to yield a still further embodiment. Thus, it is intended that the present invention cover such modifications and variations as come within the scope of the appended claims and their equivalents.

Referring to FIG. 2, a bitmap of an exemplary UUID 30 generated by the system and method of the present invention is illustrated. A bitmap, which is also referred to as a bit array, bitset, bit string, or bit vector, is an array data structure that stores bits. A bit array is a mapping from some domain (almost always a range of integers) to values in the set comprising the values zero (0) and one (1). The values may be interpreted as on/off, high/low, dark/light, absent/present, locked/unlocked, valid/invalid, et cetera. Importantly, there are only two (2) possible values for each bit.

Continuing with FIG. 2, UUID 30 may include a time value field 32, a metadata field 34 and a random number field 36, each of which will be discussed in more detail below. As can be seen from FIG. 2, UUID 30 is comprised of N+1 bits. As also can be seen from FIG. 2, the bits are logically ordered from right to left, with the most significant bit, bit N, being on the left and the least significant bit, bit zero (0) on the right. As can also be seen from FIG. 2, the bits comprising the time value field 32 are more significant than the bits comprising the metadata field 34. Similarly, the bits comprising the metadata field 34 are more significant than the bits comprising the random number field 36.

It should be noted that FIG. 2, and FIGS. 3-5, illustrate various embodiments of the UUID of the present invention where the bits are logically ordered from right to left. As can be appreciated, the physical order of the bits may be either right to left or left to right, depending on the endianness of the computer processor architecture of the device generating the UUID. For example, the physical bits of a little endian computer architectures have increasing numeric significance with increasing memory addresses (or increasing time). An example of a little endian processor architecture is the x86 series of computer microprocessor instruction set architectures based on the Intel 8086 CPU. Big endian architectures, however, have physical bits with decreasing numeric significance with increasing memory addresses (or increasing time). A well-known series of processors that use the big-endian format include the Motorola 6800. The invention, however, is not limited to any particular endianness or physical bit order for the computer processor architecture of the device generating the UUID.

Continuing with FIG. 2, UUID 30 includes a random number field 36, in which a random number may be stored. The random number of field 36 may be generated by a suitable random number generator, such as, but not limited to, a conventional random number generator. A random number generator is a computational or physical device designed to generate a sequence of numbers or symbols that lack any pattern, i.e. appear random. A suitable conventional random number generator also may be an algorithm that may be referred to as a pseudorandom number generator. As may be appreciated, a pseudorandom number generator, also known as a deterministic random bit generator, is an algorithm for generating a sequence of numbers that approximates the properties of random numbers.

UUID 30 also includes a metadata field 34. The metadata value 34 may include a value that represents information about the type, version, format, content, and/or other features of UUID 30. For example, the metadata value 34 may include a value that represents information about the number of bits of the UUID, the number of fields of the UUID, and/or the arrangement and size of the fields of UUID 30.

UUID 30 also includes a time value field 36. The value stored in the time value field 36 is a current time, which may be a value that represents a system time of a computer that generated, or is otherwise associated with the generation of, UUID 30 at the time the UUID was generated. The time value field 36 may be contained in the most significant bits of UUID 30, so that values of the UUIDs are increasing over time, or, at least until the time value is reset, after a predetermined time period, for example.

The system time of the computer generating the UUID 30 is generated by the computer's system clock and may be stored in any suitable format in the time value field 36. The system time may be expressed, for example, as an integer representing the number of ticks, such as milliseconds, that have occurred from an arbitrary starting date, which may be referred to as the epoch. For example, Unix systems encode system time (“Unix time”) as the number of seconds elapsed since the start of the Unix epoch at 1 Jan. 1970 00:00:00 UT, with exceptions for leap seconds. In Windows-based operating systems, system time may be provided as both SYSTEMTIME, represented as a year/month/day/hour/minute/second/milliseconds value, and FILETIME, represented as a count of the number of 100-nanosecond ticks since 1 Jan. 1601 00:00:00 UT as reckoned in the proleptic Gregorian calendar, but returns the current time to the nearest millisecond.

System time also may be converted to and expressed as a calendar time, which is more easily comprehended by humans. For example, the Unix system time 1000000000 seconds since the beginning of the epoch translates into the calendar time 9 Sep. 2001 01:46:40 UT. Such conversions may also require adjustments for time zones, daylight saving time (DST), leap seconds, and the user's locale settings, which may be handled by library subroutines. Library routines also may convert calendar times into system times.

The system time for the UUID of the present invention may be represented as an integer or as a calendar time, with an integer being preferred.

System time also may be expressed as in one of two time standards: localtime or Coordinated Universal Time (“UTC”). As may be appreciated, the localtime standard is dependent on the current time zone in which the computer generating the UUID is located. The UTC standard, however, is a global time standard and is independent of the current time zone in which the computer generating the UUID is located. The standard used by hardware clock (CMOS clock, the time that appears in BIOS) is defined by the operating system. By default, Windows-based operating systems use the localtime standard, Mac OS operating systems use the UTC standard, and UNIX-like operating systems vary. An operating system that uses the UTC standard, generally, will deem the hardware clock time to be the UTC time, and will adjust the UTC time during boot-up to be the current time for the time zone in which computing device is located.

In a preferred embodiment, the time standard used in generating the UUID of the present invention is the UTC standard.

As may be appreciated, using more bits can increase the range of the time values, or it can increase the resolution of the time value. The resolution of the time value is the smallest unit of time measurable. As an illustrative and non-limiting example, if 8 (eight) bits are used to store a time value and if the resolution is 1 (one) second, then 256 different values can be stored and the range of time values is from zero (0) to 255 seconds.

As may be appreciated, there are practical limits to the size of the UUID and, therefore, the size of the time value stored in the time value field of a UUID. Thus, in an embodiment of the invention, when a UUID 30 is created, the value of the time value field 36 is set to the current time within a predetermined period. The predetermined period is a time period during which the time value, which is the current time of the computer generating UUID 30, does not repeat or re-occur. The predetermined period is necessarily a function of the size of the time value field, and the time resolution of UUID 30. The predetermined time period, therefore, may be selected so that is large enough to that the current time does not repeat or re-occur within a period of time that is reasonable for the application. For example, the predetermined period may have a duration of 1,000 years, or any other suitable duration, as will be discussed in greater detail below.

As discussed above, the current time within the predetermined period (e.g., the time value in the time value field 36) may be expressed as numerical value, such as an integer, representing a sequential count of time units that have elapsed from a predetermined starting point in time, i.e., an epoch. For example and not for the purpose of limiting the scope of the invention, time units of 0.1 millisecond, 1 millisecond and 1 second may be used, although other suitable time units may also be used. The starting point may be characterized as being a point in time at which zero (0) time units have elapsed, and the starting point may be any suitable frame of reference discussed above or otherwise known, such as, but not limited to, UTC.

The current time within the predetermined period (e.g., the time value in the time value field 36) may represent a numeric value that is stored as a single number comprised of bytes, which are comprised of bits, stored in a logical order, most significant bit/byte to least significant bit/byte.

Depending upon the size and resolution of the time value field 36 (e.g., the finite number of bits in the time value field and the size of the time unit), the predetermined time period may have a variety of durations. For example, the predetermined time period may be two (2) years, 139 years, 1,000 years and/or any other suitable duration. As may be appreciated, however, the duration of the predetermined time period may vary as the total size (i.e, bits) of the UUID 30 varies, as the division of bits between the random number, metadata and time value fields 32, 34, 36 varies, or as other features of UUID 30 may be varied

The predetermined period, which is a finite value, may be characterized as being a time period that extends from a lowest time value to a maximal storable time value. Thus, the current time value may start with the lowest time value, and each time the maximal storable time value is reached, the current time value returns to the lowest time value. As may be appreciated, the lowest time value may be zero (0) or any other suitable value, and the maximal storable time value depends on the size and resolution of the time value field. Various maximal storable time values are discussed in more detail below in connection with UUID's of various sizes.

As may also be appreciated, the clock arithmetic described above may also be referred to as modular arithmetic, although the invention is not limited to the use of modular arithmetic. Modular arithmetic is a system of arithmetic for integers, where numbers “wrap around” upon reaching a certain value, i.e., the modulus. A familiar use of modular arithmetic is a 12-hour clock, in which a day is divided into two 12-hour periods. If the time is 7:00 now, then 8 hours later it will be 3:00, not 7+8=15, because clock time “wraps around” every 12 hours. Thus, in 12-hour time, there is no “15 o'clock”. Similarly, if a clock starts at 12:00 (noon) and 21 hours elapse, then the time will be 9:00 the next day, rather than 33:00. Since the hour value starts over after it reaches 12. Thus, 12-hour clock arithmetic is arithmetic modulo 12 and the value 12 is congruent to 12 itself, but also to 0.

Modular arithmetic is also related to the concept of the remainder in division. The operation of finding the remainder is sometimes referred to as a modulo operation. The difference is in the use of congruency, indicated by ‘≡’, and equality indicated by “=”. Equality implies specifically the “common residue”, the least non-negative member of an equivalence class. When working with modular arithmetic, each equivalence class is usually represented by its common residue, for example, 38≡2 (mod 12), which can be found using long division. It follows that, while it is correct to say 38≡14 (mod 12), and 2≡14 (mod 12), it is incorrect to say 38=14 (mod 12) (with “=” rather than “≡”).

As may be appreciated, a value representing the duration of the predetermined time period may be thought of as the modulus and the time value of UUID 30 may be thought of as the remainder of division of the current time by a value representing the duration of the predetermined time period, i.e., the modulus.

FIGS. 3-5 illustrate bitmaps of exemplary UUID's generated by the system and method of the present invention. Referring specifically to FIG. 3, a bitmap of an exemplary, relatively large UUID 130 is illustrated. UUID 130 may be generated in the same manner as UUID 30, except for variations noted below and variations that will be apparent to one of ordinary skill in the art. Features of UUID 130 that are identical, similar and/or function in at least some ways similarly to corresponding components of UUID 30 have reference numbers incremented by 100.

As shown by the bit numbering in FIG. 3, UUID 130 includes 176 bits that may be numbered from zero (0) to 175. As discussed above, for purposes of illustration, bit numbering starts at the right with zero (0), which is the least significant bit, and is incremented by one (1) for each subsequent bit position. Alternatively, bit numbering may be from left to right, in which case the bit numbering starts at zero (0) for the most significant bit. Continuing with FIG. 3, UUID 130 comprises a random number field 132. The random number field 132 of UUID 130 may be comprised of 123 bits, ranging from bit zero (0) through the bit 122. As discussed above, a random number generator, or a pseudo random number generator, may be used to generate a random number that is stored in random number field 132. With the random number field 132 being comprised of 123 bits, about 1.70141E₊38 different random numbers may be stored in the random number field.

UUID 130 also comprises a metadata field 134. The metadata field 134 of UUID 130 may be comprised of four (4) bits, ranging from bit 123 through bit 126. While the metadata field is comprised of four (4) bits in an exemplary embodiment of the invention, the invention is not limited to the use of four (4) bits for the metadata field and a UUID having more or fewer bits is within the scope of the invention. The metadata field 134 may contain a value that represents, for example, the size and format of the UUID.

The value in metadata field 134 also may allow for identification of a specific implementation of the UUID by identifying a particular way of determining a random number value and/or a time value. For example, a value representing a simple sequential version number (e.g., 0001) may be assigned to the metadata field, indicating the use of a particular pseudorandom number generating algorithm, a time reference point, interval size and modulus. In the event that a change is made to the UUID, for example, a different pseudorandom number generating algorithm is used, the version number stored in the metadata field may be incremented to, for example, 0010, indicating the use of the different pseudorandom number generating algorithm.

In an alternative embodiment, bits 1-3 of the metadata field may be reserved and bit 4 may be used as a flag to indicate whether the time value represents a local system time or UTC time. Insofar as the metadata field identifies a particular implementation or class or type of implementation, they may be used to indicate that a particular UUID implementation is suitable for or unsuitable for a particular application, application group or class of applications. In other words, an insecure pseudorandom number generation algorithm may not be suitable for an application that requires stringently unpredictable random values.

UUID 130 also comprises a time value field 136. The time value field 136 of UUID 130 may be comprised of 49 bits, ranging from bit 127 through the bit 175. The time value field 136 may contain a value that represents, for example, the time that UUID 130 was generated.

The resolution (e.g., time units) of time value field 136 may be 0.1 milliseconds. Thus, if the time value field 136 is comprised of 49 bits and the time resolution is 0.1 milliseconds, there may be about 3.16E+13 different time values that may be stored in time value field 136. Stated differently, there may be about 1,000 years, before a value in the time value field 136 is repeated.

As discussed in greater detail below, in addition to the relatively large UUID 130, the system and method of the present invention may be used to generate relatively medium sized and small UUIDs 230, 330. The optimal size of the UUID depends on the situation, e.g., the relative importance of the size of the UUID and the number of possible unique values. For example, a relatively large UUID 130 may be used when the desire for a large number of unique values outweighs any concerns about the resources required to generate, process and store a relatively large UUID. Irrespective, each of the UUIDs 130, 230, 330 may include a time component in the most significant bytes in a manner that provides ever increasing values and, thus, avoids the disadvantages associated with UUIDs in which a random number is stored in the most significant bytes.

Referring to FIG. 4, a bitmap of an exemplary, relatively medium sized UUID 230 is illustrated. UUID 230 may be generated in the same manner as UUID 30, except for variations noted below and variations that will be apparent to one of ordinary skill in the art. Features of UUID 230 that are identical, similar and/or function in at least some ways similarly to corresponding components of UUID 30 have reference numbers incremented by 200.

As shown by the bit numbering in FIG. 4, UUID 230 includes 80 bits that may be numbered from zero (0) to 79. As discussed above, for purposes of illustration, bit numbering starts at the right with zero (0), which is the least significant bit, and is incremented by one (1) for each subsequent bit position. Alternatively, bit numbering may be from left to right, in which case the bit numbering starts at zero (0) for the most significant bit.

Continuing with FIG. 4, UUID 230 comprises a random number field 232. The random number field 232 of UUID 230 may be comprised of 34 bits, ranging from bit zero (0) through the bit 33. As discussed above, a random number generator, or a pseudo random number generator, may be used to generate a random number that is stored in random number field 232. With the random number field 232 being comprised of 34 bits, about 275 billion different random numbers, or more specifically, about 274,877,906,944 different random numbers may be stored in the random number field.

UUID 230 also comprises a metadata field 234. The metadata field 234 of UUID 230 may be comprised of four (4) bits, ranging from bit 34 through bit 37. The metadata field 234 may contain a value that represents, for example, the size and format of the UUID.

UUID 230 also comprises a time [value] 236. The time value field 236 of UUID 230 may be comprised of 42 bits, ranging from bit 38 through the bit 79. The time value field 236 may contain a value that represents, for example, the time that UUID 230 was generated.

The resolution (e.g., time units) of time value field 236 may be 1 millisecond. Thus, if the time value field 236 is comprised of 42 bits and the time resolution is 1 millisecond, there may be about 4.39E+12 different time values that may be stored in time value field 236. Stated differently, there may be about 139 years, before a value in the time value field 236 is repeated. As may be appreciated, 139 years is greater than the lifespan of most people, and is also greater than the lifespan of most data.

Referring to FIG. 5, a bitmap of an exemplary, relatively small UUID 330 is illustrated. UUID 330 may be generated in the same manner as UUID 30, except for variations noted below and variations that will be apparent to one of ordinary skill in the art. Features of UUID 330 that are identical, similar and/or function in at least some ways similarly to corresponding components of UUID 30 have reference numbers incremented by 300.

As shown by the bit numbering in FIG. 5, UUID 330 includes 48 bits that may be numbered from zero (0) to 47. As discussed above, for purposes of illustration, bit numbering starts at the right with zero (0), which is the least significant bit, and is incremented by one (1) for each subsequent bit position. Alternatively, bit numbering may be from left to right, in which case the bit numbering starts at zero (0) for the most significant bit.

Continuing with FIG. 5, UUID 330 comprises a random number field 332. The random number field 332 of UUID 330 may be comprised of 18 bits, ranging from bit zero (0) through the bit 17. As discussed above, a random number generator, or a pseudo random number generator, may be used to generate a random number that is stored in random number field 332. With the random number field 332 being comprised of 18 bits, about 4.2 million different random numbers, or more specifically, about 4,194,304 different random numbers may be stored in the random number field.

UUID 330 also comprises a metadata field 334. The metadata field 334 of UUID 330 may be comprised of four (4) bits, ranging from bit 18 through bit 21. The metadata field 334 may contain a value that represents, for example, the size and format of the UUID.

UUID 330 also comprises a time [value] 336. The time value field 336 of UUID 330 may be comprised of 26 bits, ranging from bit 22 through the bit 47. The time value field 336 may contain a value that represents, for example, the time that UUID 330 was generated.

The resolution (e.g., time units) of time value field 336 may be 1 second. Thus, if the time value field 236 is comprised of 26 bits and the time resolution is 1 second, there may be about 6.31E+7 different time values that may be stored in time value field 336. Stated differently, there may be about two (2) years, before a value in the time value field 336 is repeated. As may be appreciated, two (2) years is sufficient for many applications.

As may be appreciated, the relatively small UUID 330 may be useful in applications where the space is very constrained, and the combination of data volume, throughput rates, lifespan and lifetime footprint allow for a smaller time component and a smaller random number space. As a more specific example and not for the purpose of limiting the scope of the present invention, the relatively small UUID 330 may be useful in some embedded system applications. Embedded system applications may include, but are not limited to, cell phones, digital systems, household appliances, automobiles and the like.

More generally and as other examples, the UUIDs 30, 130, 230, 330 may be implemented using SQL Server's custom data type extensibility feature and a .NET class library for database developers. As other examples, the UUIDs 30, 130, 230, 330 may be incorporated into database platforms and middleware (e.g., .NET provider library). More generally, the UUIDs 30, 130, 230, 330 may be implemented and used in any suitable manner.

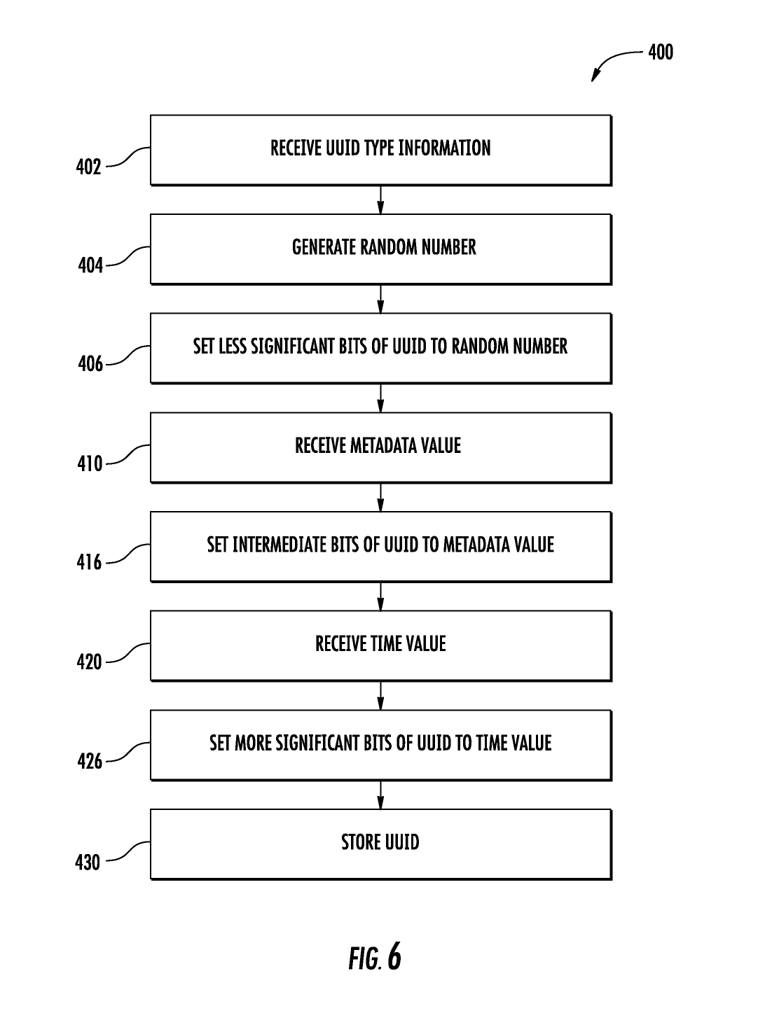

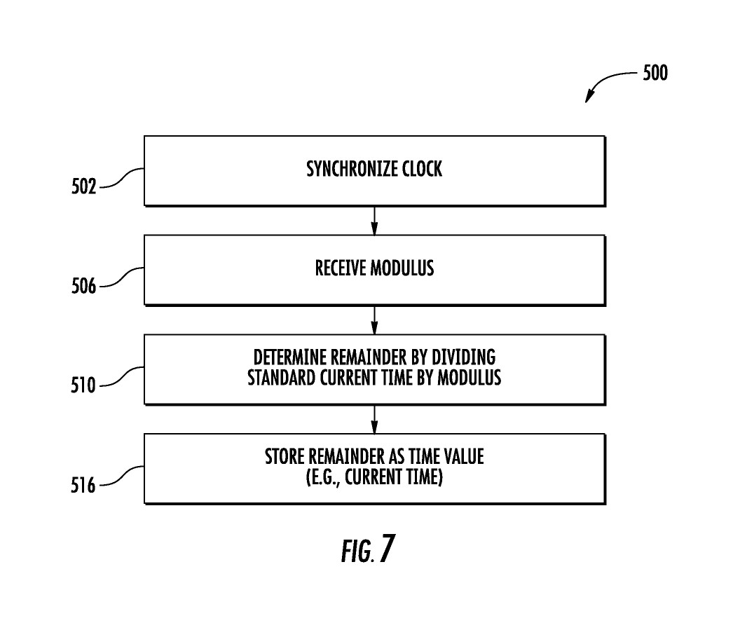

FIG. 6 is a process flow diagram illustrating an exemplary process 400 that may be used for generating a UUID, such as one of the UUID's 30, 130, 230, 330 described above in accordance with an aspect of this disclosure. For ease of readability and in the context of FIGS. 6 and 7, the UUIDs 30, 130, 230, 330 are generally referred to as the UUID, the random number fields 32, 132, 232, 332 are generally referred to as the random number field, the metadata fields 34, 134, 234, 334 are generally referred to as the metadata field, and the time value fields 36, 136, 236, 336 are generally referred to as the time value field, and so on.

As can be seen from FIG. 6, in block 402, optionally, information is received as to which type of UUID is to be generated. Alternatively and depending upon the system generating the UUID, the system may be configured such that a default type of UUID is generated, such that processes illustrated in block 402 are not necessarily performed each time a UUID is generated. The type of UUID selected in block 402 may be tailored to different applications by selecting the various characteristics of each type of UUID, i.e., the size of the UUID, the size of the respective fields of the UUID, the resolution of the time value field of the UUID, etc. For example, in block 402, a predetermined modulus may be selected from a plurality of predetermined moduli, which may be selected may vary depending on whether an application calls for a relatively large, medium-sized and small UUIDs. The plurality of predetermined moduli may comprise values of, or values of about, 3.16E+12, 4.39E+12, and 6.31E+7, or any other suitable values. Alternatively, in some embodiments, rather than selecting from a plurality of predetermined moduli in block 402, a single predetermined modulus may be used, in which case the step of selecting a modulus in block 402 may be omitted.

Continuing with FIG. 6, in block 404, a random number may be generated via the computer processor, or the random number may be provided or otherwise obtained in any suitable manner, as discussed above. Processing control is transferred to block 406.

In block 406, the less significant bits of the UUID are set to the random number generated by the process illustrated in block 404. More specifically, in block 406, the least significant bits of the UUID may be set to the random number generated in block 404. The bits set to the random number may be collectively referred to as the random number field of the UUID. The bits of the random number field may be arranged from left to right, with the more significant portion of the random number on the left of the random number field and the less significant portion of the random number on the right of the random number field. Alternatively, the bits comprising random number and/or the random number field may be arranged in any suitable manner without departing from the scope of the present invention. Processing control is transferred to block 410.

With continued reference to FIG. 6, in block 410, a metadata value, which represents information about the UUID to be generated, may be received. The metadata value about the UUID to be generated may be generated by the computer processor, or the metadata may be received or otherwise obtained in any suitable manner, such as via a computer input device. The metadata value may provide information about the type, version and/or other suitable information about the UUID. Processing control is transferred to block 416.

In block 416, the metadata field, which is comprised of the intermediate bits of the UUID, are set to the metadata value received in block 410. More specifically, in block 416, the middle bits of the UUID may be set to the metadata value received in block 410. In the metadata field, the bits representing the metadata value may be arranged from left to right, with the more significant portion of the metadata value on the left within the metadata field, and the less significant portion of the metadata value on the right within the metadata field. Alternatively, the metadata value may be arranged in any suitable manner without departing from the scope of the present invention. Processing control is transferred to block 420.

Continuing with FIG. 6, in block 420, a time value may be received via the computer processor. The time value received in block 420 may be generated in the manner discussed above and/or below, or in any other suitable manner. Processing control is transferred to block 426.

Continuing with FIG. 6, in block 426, the more significant bits of the UUID are set to the time value received in the process illustrated by block 420. More specifically, in block 426, the most significant bits of the UUID may be set to the time value received in block 420. The time value may be arranged from left to right, with the more significant portion (e.g., the slower changing digits) of the time value on the left of the time value field, and the less significant portion (e.g., the faster changing digits) of the time value on the right within the time value field. Alternatively, the bits representing the time value may be arranged in any suitable manner without departing from the scope of the present invention. Processing control is transferred to block 430. In block 430, the UUID may be stored in computer memory. The UUID may be stored volatile and/or nonvolatile memory; typically, however, the UUID is stored in nonvolatile, i.e., persistent and non-transitory, memory.

As can be appreciated, steps of the process 400 and other processes of this disclosure may be performed in any suitable manner. For example, the steps illustrated in blocks of process 400 may be arranged in different orders or occur simultaneously. Likewise, whereas one or more steps of the process 400 and other processes of this disclosure may be discussed in the context of a feature such as a computer, computer processor or computer memory, the steps may be performed or otherwise associated with one or more of these features. For example, the steps may be performed by the same computer processor or different computer processors that may be associated with one another. Similarly, the blocks of the exemplary process 500 illustrated in FIG. 7 may be performed in any suitable order, or may be performed by the same computer processor or different computer processors that may be associated with one another.

FIG. 7 is a process flow diagram illustrating an exemplary process 500 that may be used for generating the time value that is received in block 420 of process 400, in accordance with an aspect of this disclosure. Referring to FIG. 7, in block 502, the system clock associated with the computer may optionally be synchronized in a conventional manner, such as by using current UTC time. This synchronization may be performed by an Internet connection, a telephone connection, or in any other suitable manner. Alternatively, the system clock of the computer may be synchronized with any other suitable external source of time, or the synchronization may be omitted, or performed infrequently. The frequency at which any synchronization in block 502 may occur may depend on numerous known factors associated with clocks, such as the rate at which the system clock drifts relative to the current UTC time or another suitable external source of time. In addition, the synchronization step illustrated in block 502 may be useful when the more than one computer is providing UUIDs in accordance with this disclosure, and the UUIDs from the different computers are used together. For example and not for the purposes of limiting the scope of the present invention, the UUIDs provided from multiple computers may be used together in implementing a system and method of creating and processing electronic promotional offers. Processing control may be transferred to block 506.

With continued reference to FIG. 7, in block 506 of process 500 and/or block 402 of process 400, the modulus for use in the process 500 may be received. As discussed above, the modulus may be thought of as a value representing the duration of the predetermined time period, may be received or otherwise obtained in a suitable manner. Processing control is then transferred to block 510.

As shown in FIG. 7, in block 510, a remainder is determined via the computer processor by, for example, dividing a value representing the current time of the computer generating a UUID by a value representing the modulus received in block 506 and/or block 402. In block 510, the current time and the modulus may each be expressed as an integer. In block 510, the remainder may be determined using a software module, or in any other suitable manner. For example, it may be appreciated that a modulo process, operation or routine may be performed by programming languages such as, but not limited to, C++. Processing control is then transferred to block 516.

In block 516, the remainder determined in the process illustrated in block 510 may be stored in the time value field of a UUID as a time value, such as a current time within a predetermined time period.

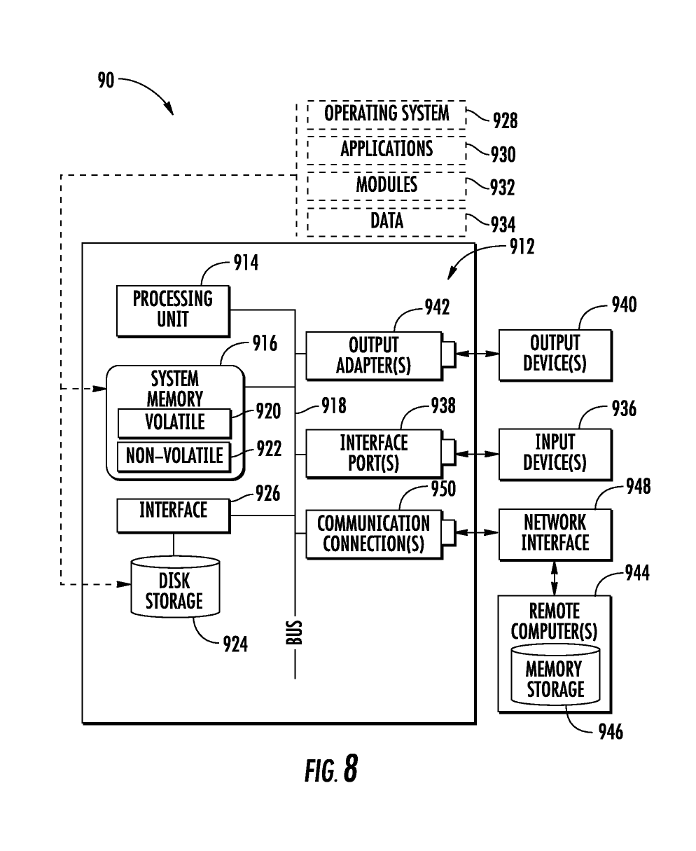

FIG. 8 illustrates exemplary hardware and software components that may be used to implement an embodiment of the present invention. While aspects of the invention may be described in the general context of computer-executable instructions, such as program modules, executed by one or more computers or other devices, those skilled in the art will recognize that the invention can also be implemented in combination with other program modules and/or as a combination of hardware and software. Generally, however, program modules include routines, programs, objects, components, data structures, etc. that can perform particular tasks or implement particular data types. The operating environment 90 is an exemplary suitable operating environment and does not limit the scope of the invention. Other known computer systems, environments, and/or configurations may be suitable for use with the invention.

Referring to FIG. 8, an exemplary environment 90 for implementing various aspects of the invention includes a computer 912, which includes a processing unit 914, a system memory 916, and a system bus 918. The system bus 918 couples the system components, including coupling the system memory 916 to the processing unit 914. The processing unit 914 can be any of various processors available. The system bus 918 can be any of the available types of bus structures using any variety of available bus architectures. The system memory 916 typically includes volatile memory 920 and nonvolatile memory 922.

The computer 912 also may include removable/nonremovable, volatile/nonvolatile computer storage media, for example, a disk storage 924. Disk storage devices 924 may be connected to the system bus 918 via removable or non-removable interface 926.

FIG. 8 also illustrates software that allows interaction between users and computer resources, which may include an operating system 928. System applications 930 are allocated resources by operating system 928 through program modules 932 and program data 934 stored either in system memory 916 or on disk storage 924. Aspects of the present invention may be implemented with various operating systems or combinations of operating systems.

A user enters commands or information into computer 912 through input devices 936, which connect to processing unit 914 through the system bus 918 via interface ports 938. Input devices may include tables, touch screens, keyboards, scanners, etc., which can be used to input data. Output devices 940 use some of the same type of ports as input devices 936. Output adapter 942 may be provided because some output devices 940 like monitors, speakers and printers may require special adapters. Other devices and/or systems of devices provide both input and output capabilities such as remote computers 944.

Computer 912 can operate in a networked environment using logical connections to one or more remote computers, such as remote computers 944. The remote computers 944 can be a personal computer, a server, a router, a network PC, a workstation, a microprocessor based appliance, a peer device or other common network node, which may include many or all of the elements of computer 912. While only a single memory storage device 946 is shown, remote computers 944 may be logically connected to computer 912 through a network interface 948 and physically connected via communication connection 950.

Although the present invention has been described with exemplary embodiments, it is to be understood that modifications and variations may be utilized without departing from the spirit and scope of the invention, as those skilled in the art will readily understand. Such modifications and variations are considered to be within the purview and scope of the appended claims and their equivalents.

1. A computer implemented method of generating a plurality of universally unique identifiers (“UUIDs”) each of the plurality of UUIDs comprising a plurality of bits arranged in order from a most significant bit to a least significant bit, and for each of the plurality of UUIDs, the method comprises:
generating, via a computer processor, a time value, wherein the time value represents a current time of a computer associated with the computer processor;
setting a plurality of the more significant bits of the UUID to the time value;
setting a plurality of the less significant bits of the UUID to a random number; and
storing the UUID in a memory.

2. The computer implemented method of claim 1, wherein the plurality of bits are arranged in order from left to right with the most significant bit on the far left and the least significant bit on the far right.

3. (canceled)

4. The computer implemented method of claim 2, wherein the plurality of more significant bits of the UUID that are set to the time value are arranged in order from left to right, with a more significant portion of the time value being on the left within the plurality of more significant bits of the UUID, and a less significant portion of the time value being on the right within the plurality of more significant bits of the UUID.

5. (canceled)

6. The computer implemented method of claim 1, wherein the plurality of more significant bits of the UUID are the most significant bits of the UUID, and the plurality of less significant bits of the UUID are the least significant bits of the UUID.

7. The computer implemented method of claim 1, further comprising:
generating a metadata value for the UUID, the metadata value identifying a format of the UUID; and
setting bits of the UUID that are between the more significant bits and the less significant bits to the metadata value.

8. The computer implemented method of claim 1, wherein the time value is a UTC time value.

9. The computer implemented method of claim 1, wherein the current time is a current time within a predetermined period.

10. The computer implemented method of claim 1, wherein generating the time value further comprises determining a remainder.

11. The computer implemented method of claim 10, wherein the reminder is a portion of a dividend that is not evenly divisible by a divisor.

12. The computer implemented method of claim 1, wherein generating the time value further comprises determining a remainder of division of the current time of the computer by a modulus.

13. The computer implemented method of claim 12, wherein the method further comprises selecting the modulus from a plurality of predetermined moduli.

14. The computer implemented method of claim 1, wherein
the current time is a current time within a predetermined period; and
generating the time value further comprises determining a remainder of division of another current time of the computer by a modulus.

15. The computer implemented method of claim 14, wherein the method further comprises synchronizing the another current time of the computer to Coordinated Universal Time.

16. The computer implemented method of claim 14, wherein the another current time of the computer is a system time of the computer.

17. A computer implemented method of generating a plurality of universally unique identifiers (“UUIDs”), each of the plurality of UUIDs comprising a plurality of bits arranged in order from a most significant bit to a least significant bit, and for each of the plurality of UUIDs, the method comprises:
generating, via a computer processor, a time value, wherein the time value represents a current time of a computer associated with the computer processor, and the time value has a faster changing portion and a slower changing portion;
setting a first portion of the bits of the UUID to the slower changing portion of the time value, and setting a second portion of the bits of the UUID to faster changing portion of the time value, wherein the second portion of the more significant bits of the UUID are
proximate the first portion of the bits of the UUID and comprising less significant bits of the UUID than the first portion of the bits of the UUID, and
setting a third portion of the bits of the UUID that are less significant than the second portion of the bits of the UUID to a random number; and
storing the UUID in a memory.

18-19. (canceled)

20. The computer implemented method of claim 17, wherein the first portion of the bits of the UUID are the most significant bits of the UUID, and the third portion of the bits of the UUID are the least significant bits of the UUID.

21. The computer implemented method of claim 17, further comprising:
generating a metadata value for the UUID, the metadata value identifying a format of UUID; and
setting bits of the UUID that are between the second portion of the bits of the UUID and the third portion of the bits of the UUID to the metadata value.

22. The computer implemented method of claim 17, wherein the time value is a Coordinated Universal Time time value.

23. The computer implemented method of claim 17, wherein the current time is a current time within a predetermined period.

24. The computer implemented method of claim 17, wherein generating the time value further comprises determining a remainder.

25. The computer implemented method of claim 17, wherein generating the time value further comprises determining a remainder of division of a current time of the computer by a modulus.

26. The computer implemented method of claim 17, wherein
the current time is a current time within a predetermined period; and
generating the time value further comprises determining a remainder of division of another current time of the computer by a modulus.

27. A computer program product comprising a non-transitory computer readable medium for generating a plurality of universally unique identifiers (“UUIDs”), each of the plurality of UUIDs comprising a plurality of bits arranged in order from left to right, with more significant bits on the left and less significant bits on the right, the computer readable medium comprising program instructions which, when executed by a computer processor, for each of the plurality of UUIDs, will cause the computer processor to
generate a time value, wherein the time value represents a current time of a computer associated with the computer processor;
set a plurality of the more significant bits of the UUID to the time value;
set a plurality of the less significant bits of the UUID to a random number; and
store the UUID in a memory.

28-30. (canceled)

31. A computer program product comprising a non-transitory computer readable medium for generating universally unique identifiers (“UUIDs”), each of the UUIDs comprising a plurality of bits arranged in order from left to right, with more significant bits on the left and less significant bits on the right, the computer readable medium comprising program instructions which, when executed by a computer processor, for each of the plurality of UUIDs, will cause the processor to:
generate a time value, wherein the time value represents a current time of a computer associated with the computer processor, and the time value has a faster changing portion and a slower changing portion;
set a first portion of the more significant bits of the UUID to the slower changing portion of the time value, and set a second portion of the more significant bits of the UUID to the faster changing portion of the time value, wherein the second portion of the more significant bits of the UUID are
proximate the first portion of the more significant bits of the UUID, and
between first portion of the more significant bits of the UUID and less significant bits of the UUID;
set a plurality of the less significant bits of the UUID to a random number; and
store the UUID in a memory.

32-33. (canceled)

34. A non-transitory computer readable medium comprising a data structure, which is usable by a program executable on a computer system, for a universally unique identifier (“UUID”) comprising:
a plurality of bits arranged from left to right, with more significant bits on the left and less significant bits on the right;
at least some of the more significant bits of the UUID being set to a time value; and
at least some of the less significant bits of the UUID being set to a random number.

35. A non-transitory computer readable medium comprising a data structure, which is usable by a program executable on a computer system, for a universally unique identifier (“UUID”) comprising:
a plurality of bits arranged from left to right, with more significant bits on the left and less significant bits on the right;
a first portion of the more significant bits of the UUID being set to a slower changing portion of a time value and a second portion of the more significant bits of the UUID being set to a faster changing portion of the time value, wherein the second portion of the more significant bits of the UUID are
proximate the first portion of the more significant bits of the UUID, and
between the first portion of the more significant bits of the UUID and the less significant bits of the UUID; and
a plurality of the less significant bits of the UUID being set to a random number.

36. A computer implemented method of generating a universally unique identifier (“UUID”) that comprises a plurality of bits that are arranged in a plurality of fields, each field including one or more of the plurality of bits, the method comprising:
using a processor to generate a time value that represents a current time;
setting a first field that includes the most significant bits of the UUID to the time value;
setting a second field of the UUID to a random number; and
storing the UUID in a memory.

37. The computer implemented method of claim 36, wherein the bits are arranged from left to right with more significant bits on the left and less significant bits on the right.

38. The computer implemented method of claim 36, wherein the time value represents the current time of a computer associated with the processor expressed as a Coordinated Universal Time value.

39. The computer implemented method of claim 36, wherein the time value represents the current time of a computer associated with the processor expressed as a localtime value.

40. The computer implemented method of claim 36, wherein the time value is an integer representing a number of constant-value time increments that have occurred since a pre-defined epoch.

41. The computer implemented method of claim 36, further comprising setting a third field of the UUID to a value that provides information regarding the format of the UUID.

42. The computer implemented method of claim 37, wherein the more significant portion of the time value is stored in a left portion of the first field and the less significant portion of the time value stored in a right portion of the first field.
